(19) United States
(12) Patent Application Publication
(10) Pub. No.: US 2010/0247030 A1
(43) Pub. Date: Sep. 30, 2010

(54) OPTOELECTRONIC WIRING BOARD INCLUDING OPTICAL WIRING AND ELECTRICAL WIRING AND METHOD OF MANUFACTURING OPTOELECTRONIC WIRING DEVICE USING THE SAME

(76) Inventor: Hideto FURUYAMA, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/700,116

(22) Filed: Feb. 4, 2010

(30) Foreign Application Priority Data
Mar. 26, 2009 (JP) 2009-076704

(51) Int. Cl. G02B 6/12; G02B 6/36; H01L 33/00

(52) U.S. Cl. 385/14; 385/88; 438/25; 257/E33.076

(57) ABSTRACT

An optoelectronic wiring board includes an optical wiring, an electrical wiring, an optical input/output portion, a dummy optical input portion, and a dummy optical waveguide. The optical wiring includes an optical waveguide. The electrical wiring includes an electrically conductive material. The optical input/output portion transmits and detects optical signal with and from the optical waveguide, an optical semiconductor device or an external light guide being disposed on the optoelectronic wiring board. The dummy optical input portion provided adjacent to the optical input/output portion. The dummy optical waveguide is connected to the dummy optical input portion and has an optical end portion which is provided at an end opposite to the dummy optical input portion and absorbs or scatters light which is incident on the dummy optical input portion.

### CROSS-REFERENCE TO RELATED APPLICATIONS

This application is based upon and claims the benefit of priority from prior Japanese Patent Application No. 2009-076704, filed Mar. 26, 2009, the entire contents of which are incorporated herein by reference.

### BACKGROUND

There have been proposed some optical wiring devices which optically connect LSIs. The feature of A optical wiring is, for example, that there is little frequency dependency, such as loss, in a wide frequency range from DC to 100 GHz or above, and that wiring of several-ten Gbps can easily be realized because of the absence of electromagnetic hindrance of wiring lines and ground potential variation noise. In the optical wiring device, a very high speed operation can be expected in the printed board level or rack level, and vigorous research and development have been promoted. JP2008-158440 describes that there is known, as an example, an optical wiring device which is configured such that optical semiconductor devices, etc. The optical semiconductor devices are aligned on an optoelectronic wiring board in which optical wiring and electric wiring are combined.

### SUMMARY

An optoelectronic wiring board according to aspect of the present invention includes,

an optical wiring including an optical waveguide;

an electrical wiring including an electrically conductive material;

an optical input/output portion which transmits and detects optical signal with and from the optical waveguide;

a dummy optical input portion provided adjacent to the optical input/output portion; and

a dummy optical waveguide which is connected to the dummy optical input portion and has an optical end portion which is provided at an end opposite to the dummy optical input portion and absorbs or scatters light which is incident on the dummy optical input portion.

A method of manufacturing optoelectronic wiring device using the optoelectronic wiring board includes,

making light incident on a first dummy optical waveguide through first dummy optical input portions;

subjecting an image, which is acquired from the first dummy optical input portions and a vicinity thereof, to a binarizing process;

recognizing a black part of the image, thereby detecting a position of the first dummy optical input portions; and

disposing an optical semiconductor device or an external light guide on optical input/output portions of an optoelectronic wiring board, by using a result of the detection as an index.

### BRIEF DESCRIPTION OF THE DRAWING

FIG. 1 is a perspective view which schematically shows the structure of an optoelectronic wiring board according to a first embodiment;

FIG. 2 is a cross-sectional view which schematically shows the structure of the optoelectronic wiring board according to the first embodiment;

FIG. 3 is a cross-sectional view which schematically shows the structure of the optoelectronic wiring board according to the first embodiment;

FIG. 4 is a perspective view which schematically shows an assembly step of an optoelectronic wiring board according to a second embodiment of this invention;

FIG. 5 is a cross-sectional view which schematically shows an assembly step of the optoelectronic wiring board according to the second embodiment;

FIG. 6 is a top view which schematically shows an assembly step of the optoelectronic wiring board according to the second embodiment;

FIG. 7 is a perspective view which schematically shows an assembly step of the optoelectronic wiring board according to the second embodiment; and

FIGS. 8A, 8B, 8C, 8D and 8E are top views and a cross-sectional view thereof, which schematically show dummy optical waveguide shapes according to a third embodiment.

### DETAILED DESCRIPTION

Embodiments of the present invention will now be described with reference to the accompanying drawings. In the description below, common parts are denoted by like reference numerals throughout the drawings.

In first to third embodiments and modifications thereof, a optoelectronic FPC (Flexible Printed Circuit) is described as an example of an optoelectronic wiring board. First to third embodiments of the present invention, however, is not limited to the optoelectronic FPC, and First to third embodiments of the present invention is similarly applicable to a rigid board such as an ordinary printed wiring board (PWB), and various materials are usable therefor. For example, use may be made of various materials, for example, (glass) epoxy which is a general PWB material, polyimide which is a general FPC material, Teflon (trademark) which is used for a low-dielectric-constant board, and acryl or silicone, which is used for a optical waveguide. Furthermore, ceramic materials may be used. Besides, mixture materials of these materials may be used. Optical and electrical wiring patterns and the number of wirings may be determined according to purposes of use. The terminal end structure of a optical waveguide (the structure of an optical input/output portion) may be arbitrarily chosen, and these possible variations do not depart from the spirit of the invention.

### First Embodiment

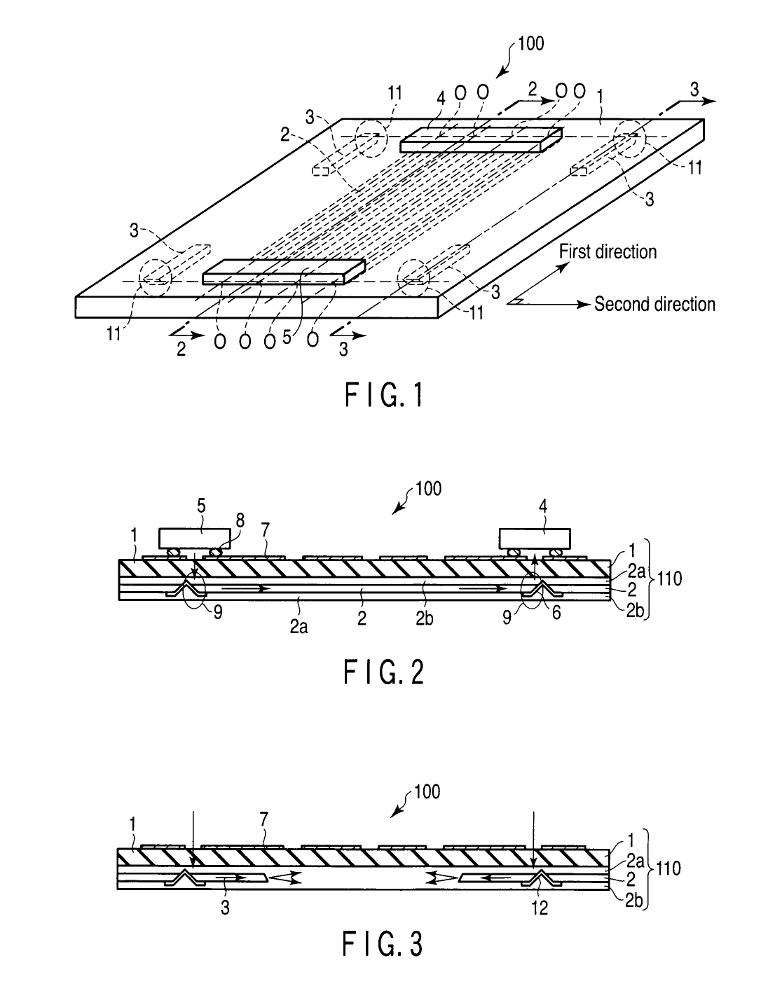

A description will now be given of an optoelectronic wiring board according to a first embodiment, and a method of manufacturing a optoelectronic wiring device using the optoelectronic wiring board. FIG. 1 is a perspective view showing a optoelectronic wiring device 100 according to the first embodiment. In FIG. 1, for the purpose of simple illustration, depiction of an electric wiring pattern is omitted. In FIG. 1, the optoelectronic wiring device 100 includes an optoelectronic wiring board substrate 1, a optical waveguide 2 (hereinafter also referred to as “optical wiring channel 2”), a dummy optical waveguide 3, a light detection element array 4 (also referred to as “optical semiconductor device 4”), and a light emission element array 5 (also referred to as “optical semiconductor device 5”). An optical signal is transmitted/received via the optical waveguide 2 between the light emission element array 5 and light detection element array 4.

FIG. 2 is a cross-sectional view of the optoelectronic wiring device 100, taken along line 2-2 in FIG. 1. In FIG. 2, the optoelectronic wiring board substrate 1 is formed of an FPC substrate film (e.g. a polyimide film with a thickness of 25 μm). The optical waveguide 2 (or a optical waveguide core, for example, a transparent epoxy resin with a thickness of 40 μm and a width of 40 μm) is configured to be surround by light confinement claddings 2A and 2B (e.g. a transparent epoxy resin having a thickness of 15 μm and a lower refractive index than the optical waveguide 2). The optoelectronic wiring board substrate 1, the optical waveguide 2, the cladding 2A and the cladding 2B constitute an optoelectronic wiring board 110.

An electric wiring 7 is formed of Cu with a thickness of, e.g. 12 μm, and metal bumps 8 is e.g. solder bumps or Au stud bumps. The optical wiring channel 2 includes a vertical upright mirror (45° mirror). The vertical upright mirror 6 is formed by processing the optical waveguide core 2 at 45° at an optical input/output portion 9, and providing the processed surface with a reflection metal 6 (e.g. Au).

An optical signal, as indicated by an arrow in FIG. 2, is emitted from a light emission element 5, and is then horizontally reflected by the 45° mirror. Thereafter, the optical signal propagates through the optical waveguide 2, and is vertically reflected by the opposite-side 45° mirror and is detected by detection element array 4.

As shown in FIG. 1, a plurality of optical wiring channels 2 are juxtaposed in a second direction which is perpendicular to a first direction. Specifically, the optical wiring channels 2 are configured such that the 45° mirrors under the optical input/output portions 9 are arranged with a predetermined pitch along the second direction. Thereby, the optical signal can be input/output in the first direction perpendicular to the second direction. In association with the optical wiring channels 2, the optical semiconductor devices 4 and 5 are configured as array elements in such a manner that optical active parts (light emission parts or light detection parts) are arranged in line with a predetermined pitch along the second direction. The optical active parts of the optical semiconductor devices 4 and 5 are mounted on the optoelectronic wiring board substrate 1 such that the optical waveguide optical axes of the optical input/output portions 9 align with the positions of the optical active parts of the optical semiconductor devices 4 and 5. The optical semiconductor device 4 and 5 or an external light guide is provided on the optoelectronic wiring board 1.

The 45° mirror 6 may be formed by a dicing process using a blade with a 45° cross section, or by a laser ablation method in which an excimer laser beam or a CO₂ laser beam is radiated in an oblique direction. After the 45° processing, Au is deposited by evaporation on the 45° processed surface, and thereby the 45° mirror 6 is completed.

At this time, 45° mirrors 12 are also formed at positions which are spaced apart by predetermined distances in the second direction from the optical wiring channels 2 on both sides of the optical semiconductor devices 4 and 5, the 45° mirrors 12 being positioned on straight lines along which the 45° mirrors 6 of the optical wiring channels 2 are disposed. The 45° mirror 12 is formed on each a dummy optical input portion 11. This dummy optical input portion 11 is formed in the same fabrication step as the optical input portion 9. The dummy mirror 12 has the same structure as the reflective metal mirror 6. In other words, the dummy mirror 12, too, is a vertical upright mirror having a 45° surface on which Au, for instance, is deposited by evaporation. Thereby, the positions of the optical input/output portions 9 of the optical wiring channels 2 can be confirmed even after the optical semiconductor devices 4 and 5 are mounted. Specifically, intersections between imaginary extension lines of the optical wiring channels 2 and the dummy optical input portions 11, which are located on both sides of the optical input/output portions 9, that is, which are closest to the optical input/output portions 9, are the positions of the optical input/output portions 9 of the optical wiring channels 2 (points 0 in FIG. 1). By comparing the coordinates of these intersections with the outer shapes of the optical semiconductor devices 4 and 5, the inclination of mounting of the optical semiconductor devices 4 and 5 and the positional displacement of mounting thereof, for instance, can be confirmed. Thereby, good/poor confirmation and analysis of operational defects can easily be performed when components are mounted on the optoelectronic wiring board 110 and the optoelectronic wiring device 100 is assembled.

Next, referring to FIG. 3, a description is given of the optoelectronic wiring device 100 according to the present embodiment. FIG. 3 is a 3-3 cross section of FIG. 1. As shown in FIG. 3, the dummy optical input portion 11 is not simply composed of the dummy mirror 12, but is provided with a dummy optical waveguide 3 which is formed in the same process as the optical wiring channels 2. The dummy optical input portions 11 includes a recess portion which reaches from a surface of the optoelectronic wiring board 1 to the dummy optical waveguide 3. The dummy optical waveguide 3 includes the dummy mirror 12 in the recess portion, and the dummy mirror 12 reflects the light which is incident in the recess portion to the dummy optical waveguide 3. The dummy optical waveguide 3 is formed in the same direction as the optical wiring channels 2. Specifically, the dummy optical waveguide 3 is formed in parallel with the second direction perpendicular to the first direction. The dummy optical waveguides 3 are cut off at distal ends and are filled with a cladding 2a (or 2b).

Thereby, the dummy optical waveguide 3 effectively absorbs radiation light for image (pattern) recognition. Thus, at the time of pattern recognition, the dummy optical input portion 11 can surely be recognized as a black pattern. As will be described later, the “pattern recognition” means a process of binarizing a photographed image in the vicinity of the dummy optical input portion 11, and recognizing the black of the image of the dummy optical input portion 11 and the white of the image of the surrounding area of the dummy optical input portion 11. Thereby, the position (coordinates, etc.) of the image, which is recognized as black, is recognized. It is the dummy mirror 12 that is recognized as black. At this time, the light incident on the dummy optical input portion 11 is horizontally reflected by the 45° mirror 12, and is emitted from the dummy optical waveguide 3 into the cladding 2a (or 2b) at the end of the dummy optical waveguide 3. Thus, the incident light hardly returns to the dummy optical input portion 11. In short, the dummy optical input portion 11 becomes equivalent to a black pattern due to light absorption, and a black pattern with a high light/dark contrast can be realized.

As regards the optoelectronic wiring board according to the embodiment and the method of manufacturing the optoelectronic wiring device using the same, image recognition radiation light is absorbed by the optical input/output portions 9 that are provided at the end portions of the optical waveguides 2. Thereby, the shapes of the optical input/output portions 9 are detected as a positional reference. In particular, additional optical waveguides and light input/output portions, which correspond to the optical waveguides 2 and the optical input/output portions 9 provided at the end portions of the optical waveguides 2, are independently formed at parts spaced apart from the position of mounting of optical elements, etc., and the shapes of these additional dummy optical input portions 11 are detected to recognize the optical axes of the optical waveguides 2.

According to the optoelectronic wiring board of the embodiment and the method of manufacturing the optoelectronic wiring device using the same, even in the case where there is a positional displacement between the mechanically-processed dummy optical input portion 11 and the electrical wiring pattern, optical axis alignment can exactly be performed between the optical semiconductor devices 4 and 5 or external light guides (optical fibers or other optoelectronic wiring boards) and the optical waveguides. Therefore, there are provided an optoelectronic wiring board and a manufacturing method thereof, which can suppress degradation in optical wiring performance due to the positional displacement between the electric wiring pattern and the optical waveguide optical input/output portion 4, 5 (the optical semiconductor devices 4 and 5 or external light guides).

On the other hand, in a manufacturing method of an optoelectronic wiring board according to a comparative example, in many cases, positional alignment has been performed with reference to an electrical wiring pattern which is formed by a pattern process using photolithography. Thus, the precision of positional alignment is influenced by the mirror formation position precision of 45° mirror processing, as well as by the pattern alignment precision between the photolithography of the electrical wiring pattern and the photolithography of the optical waveguide pattern. In general, since the mechanical processing error of the mirror formation tends to be greater than the positional alignment error of photolithography, there is such a difficulty that the optical axis error tends to easily occur, no matter how exactly the optical waveguide pattern is formed. This being the case, as disclosed in JP2008-158440, there has been proposed a method in which optical elements, etc. are mounted by using an emission light pattern of a optical waveguide in combination as a marker. However, in this method, there are such problems that light needs to be made incident from the opposite side of the optical waveguide, and that the wavelength, at which light propagation of the optical waveguide is possible, does not agree with the light wavelength that is necessary for pattern recognition, and optimal alignment cannot be performed.

However, according to the optoelectronic wiring board of the embodiment and the method of manufacturing the optoelectronic wiring device using the same, the positions of the optical input/output portions 9 under the optical semiconductor devices 4 an 5 can surely be confirmed. Furthermore, for the illumination of image recognition, use is not made of the light of long wavelengths (in general, red to infrared) which enable easy propagation through the optical waveguide, as in JP2008-158440, but use can be made of the light of short wavelengths (e.g. blue, with wavelengths of 400 nm to 450 nm) which tends to enhance the image recognition precision. Thus, the image recognition precision itself can be enhanced. Specifically, since the light that is incident on the dummy optical input portion 11 is hardly reflected and returned in the inside, the outer boundary of the dummy optical input portion 11 can clearly be confirmed, and the exact position confirmation of the external appearance of the dummy optical input portion 11 can be realized.

Therefore, according to the optoelectronic wiring board of the embodiment and the method of manufacturing the optoelectronic wiring device using the same, the optical axis alignment between the optical waveguide 2 and the optical semiconductor device 4, 5 or external light guide can exactly be performed, while tolerating the positional error between the electrical wiring pattern by photolithography and the optical waveguide optical input/output portion by mechanical processing. With the conventional processing means being used, it is possible to remarkably improve the light transmission quality of the optical wiring part and the manufacturing yield of optoelectronic wiring devices. Therefore, the optoelectronic wiring board according to the embodiment and the method of manufacturing the optoelectronic wiring device using the same have such advantageous effects that the performance of information communication equipment, etc. can be improved by introduction/promotion of optical wiring, and this contributes to the development of industries.

As has been described above, in the optoelectronic wiring board 110 according to the present embodiment, the optical semiconductor device 4, 5 or external optical waveguide is disposed on the optoelectronic wiring board 110 including the optical wiring formed by the optical waveguide 2 and the electrical wiring 7 formed by the electrically conductive material, the optoelectronic wiring board 110 comprising the optical input/output portion 9 which transmits and detects optical signal with and from the optical waveguide 2, the dummy optical input portion 11 which is formed in the same fabrication step as the optical input/output portion 9, the dummy optical input portion 11 provided adjacent to the optical input/output portion 9, and the dummy optical waveguide 3 which is connected to the dummy optical input portion 11 and has an optical terminal end portion which is provided at an end opposite to the dummy optical input portion 11 and absorbs or scatters light that is incident on the dummy optical input portion 11.

Further, the method of manufacturing the optoelectronic wiring device 100 using the optoelectronic wiring board 110 according to the present embodiment comprises disposing the dummy optical input portion 11 on the same line as the optical input/output portion 9, and providing no electrical wiring 7 in the region that is necessary for pattern recognition of the surrounding area of the dummy optical input portion 11.

Preferably, the dummy optical input portion 11 should be provided on at least two locations in association with each optical input/output portion 9.

In addition, in the optoelectronic wiring board 110 according to the present embodiment, the optical semiconductor device 4, 5 or external light guide is disposed on the optoelectronic wiring board 110 including the optical wiring formed by the optical waveguide 2 and the electrical wiring 7 formed by the electrically conductive material, the optoelectronic wiring board 110 comprising the optical input/output portion 9 which transmits and detects optical signal with and from the optical waveguide 2, the dummy optical input portion 11 which is formed in the same fabrication step as the optical input/output portion 9, the dummy optical input portion 11 provided adjacent to the optical input/output portion 9, and the dummy optical waveguide 3 which is connected to the dummy optical input portion 11 and has an optical terminal end portion which is provided at an end opposite to the dummy optical input portion 11 and prevents light, which is incident on the dummy optical input portion 11, from being reflected to the dummy optical input portion 11.

### Second Embodiment

A second embodiment of the invention relates to a process of manufacturing the optoelectronic wiring device 100 which is configured such that the optical semiconductor device 4, 5 or external light guide is disposed on the optical input/output portion 9 of the optoelectronic wiring board 110, which has been described in the first embodiment. Specifically, a description is given of the method of manufacturing the optoelectronic wiring device 100. In this method, the photographed image of the vicinity of the dummy optical input portion 11 is subjected to a binarizing process, and the position of the dummy optical input portion 11 is detected. Using the detection result as a position index, the optical semiconductor device 4, 5 or external light guide is disposed on the optical input/output portion 9.

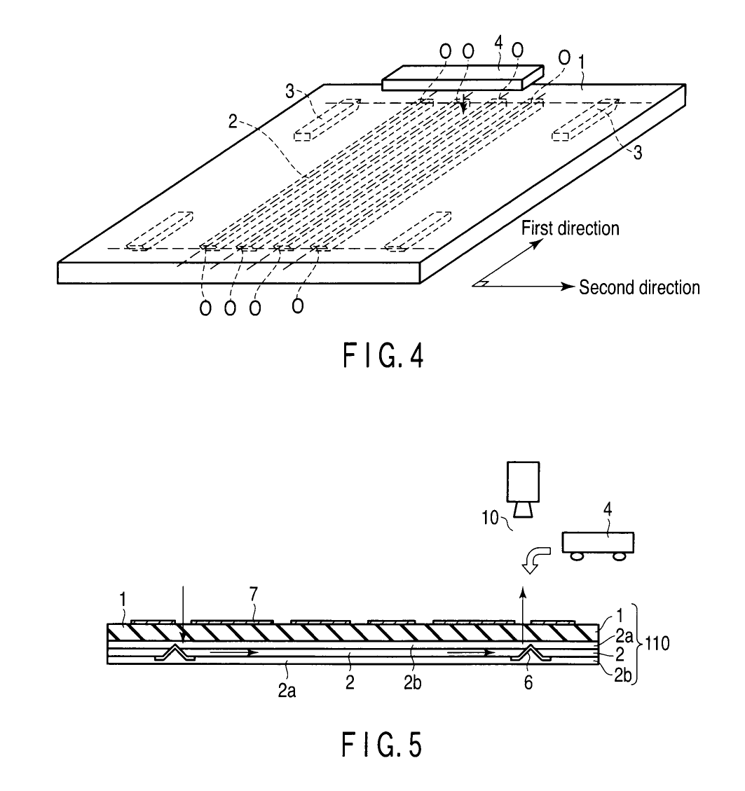

FIG. 4 is a perspective view which schematically shows a step in the manufacturing process of the optoelectronic wiring device 100 according to the second embodiment. The reference numerals in FIG. 4 are common to those in FIG. 1. FIG. 4 shows a state immediately before the optical semiconductor device 4 is mounted. FIG. 5 is a cross-sectional view illustrating the step in FIG. 4. In FIG. 5, reference numeral 10 denotes an image recognition camera. FIG. 5 shows the state in which the image recognition camera 10 radiates light (not shown) on the optoelectronic wiring board 110 to perform position confirmation by image recognition, and the optical semiconductor device 4 is mounted. At this time, there is a case where light, which has been made incident on that side of the optical input/output portion 9, which is opposite to the side of mounting of the optical semiconductor device 4, propagates as indicated by an arrow in FIG. 5 and enters the image recognition camera. Specifically, this light becomes stray light in the case of recognizing the optical input/output portion 9 of the optical wiring 2 as a black pattern.

On the other hand, even in such a case, the dummy optical input portion 11 is not affected by stray light, and is recognized as a black pattern with high contrast. The reason for this is that the end portion of the dummy optical waveguide 3 is cut off, as described above, and the light, which is incident on the dummy optical input portion 11 of the dummy optical waveguide 3, is scattered at the end portion. In short, the light, which strikes the dummy mirror 12 at the dummy optical input portion 11, is reflected. Hence, the dummy mirror 12 is recognized as black. The region including the dummy mirror 12 and its periphery is divided, with high contrast, into the black of the mirror part of the dummy mirror 12 and the white of the peripheral area thereof. Accordingly, the dummy optical input portion 11 shown in FIG. 1 is recognized as a black pattern and, on the basis of the position information (coordinates) of this black pattern, the optical semiconductor device 4, 5 or external light guide is mounted at a predetermined mounting position. Thereby, the exact optical axis determination becomes possible, without being affected by the positional error between the electrical wiring 7 and optical wiring 2 or by the processing error of the 45° mirror. This is because the positional relationship between the dummy optical input portion 11 and the optical input/output portion 9 is understood.

In theoptoelectronic wiring board 110 according to the present embodiment, since the dummy optical input portion 11 serving as a marker becomes a black pattern with high contrast, it is effective in enhancing positional precision to recognize the peripheral region of the dummy optical input portion 11 as a binary image. A binary image is an image in which a light part and a black part of an image are forcibly sorted into white and black on the basis of a predetermined threshold of luminance. The use of the binary image is an effective image recognition method for improving the recognition of a pattern boundary. Since the binary image recognition is more effective in the case of an image with higher luminance contrast, the binary image recognition is very effective if it is applied to the recognition of the dummy optical input portion 11 with a high contrast, which is shown in FIG. 1.

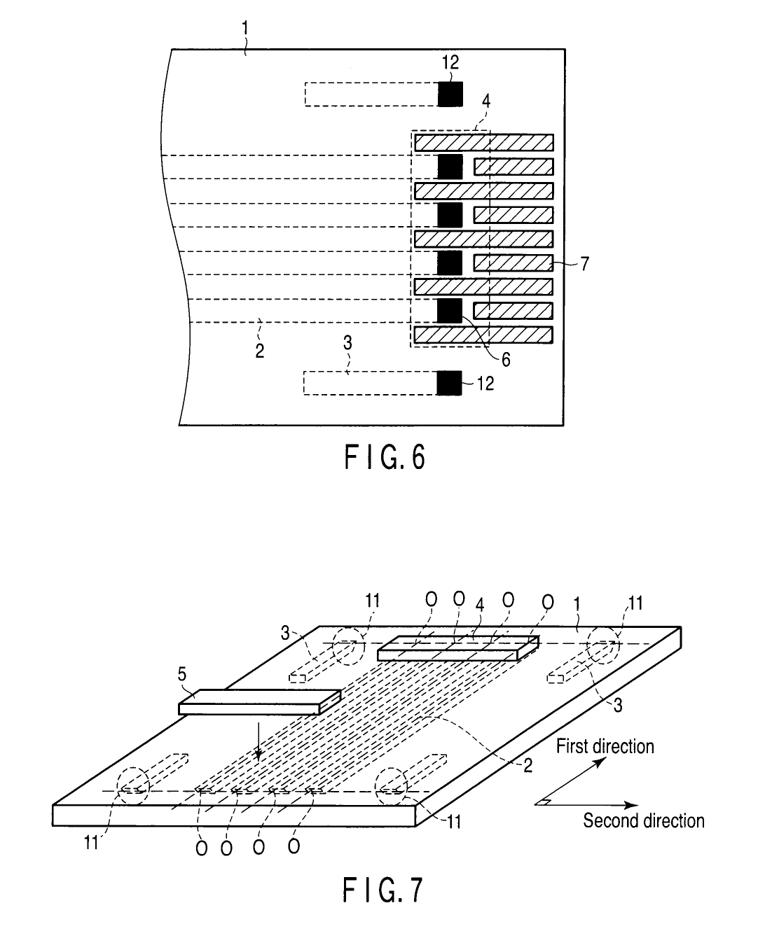

In general, wiring electrodes 7 of optical semiconductor devices 4 or 5, as shown in FIG. 6, are present in the peripheral region of the optical input/output portion 9 of the optical wiring 2. When the optical input/output portion 9 of the optical wiring 2 is to be recognized as a black pattern, such erroneous recognition tends to easily occur that the part other than the wiring electrode 7 is recognized as black since the reflective luminance of the wiring electrode 7 is high. In addition, a pattern boundary of the wiring electrode 7 tends to easily become noise of a binary image. In order to prevent this, it is necessary to set the threshold for binarization at a low level (with a bias to the dark side), and the boundary of the optical input/output portion 9 may blur and tends to have a pattern error. If the wiring electrode 7 is provided at the periphery of the dummy optical input portion 11, a similar pattern recognition error would occur. It is thus desirable that the wiring electrode 7 be not provided in a predetermined area at the periphery of the dummy optical input portion 11. Thereby, the threshold value for binarization can be set at a proper value, and more exact pattern recognition can be achieved. In the meantime, the wiring electrode 7 can transmit an electric signal which is obtained by converting an optical signal that has been received by the optical semiconductor device 4, 5 or external light guide. The wiring electrode 7 can transmit an electric signal which is input to the optical input/output portion 9 as an optical signal from the optical semiconductor device 4, 5 or external light guide.

FIG. 7 is a perspective view which schematically shows the state in which the other optical semiconductor device (light emission element array 5) is to be mounted after the optical semiconductor device (light detection element array 4) has been aligned and mounted in the step shown in FIG. 4. At this time, the problem of stray light, as illustrated in FIG. 5, does not easily occur. However, as has been described above, in order to reduce the pattern detection error, it is desirable to perform alignment by executing binary image recognition of the dummy optical input portion 11, in the predetermined peripheral area of which the wiring electrode 7 is not provided. Specifically, in the case of mounting the light emission element array 5 on the optical input/output portion 9, like the case of mounting the light detection element array 4, the alignment of the light emission element array 5 is performed by recognizing the black patterns of the dummy mirrors 12 of the optical input portions 11 which are provided on the dummy optical waveguides 3 located on both sides of the amounting area of the light emission element array 5.

### Third Embodiment

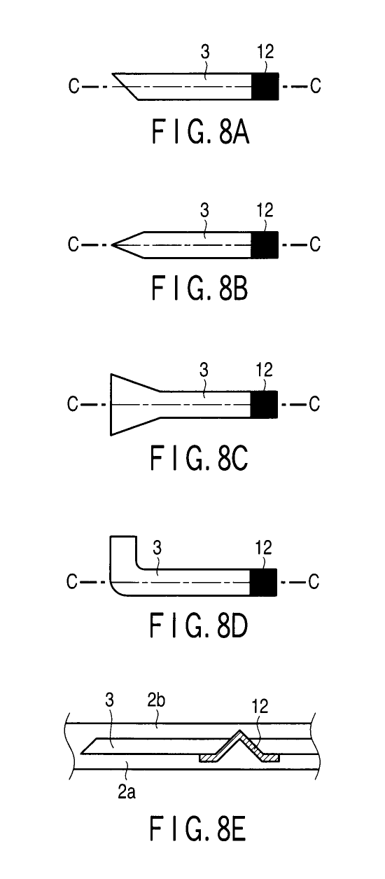

Next, a description is given of an optoelectronic wiring board according to a third embodiment and a method of manufacturing a optoelectronic wiring device using the same. Referring to FIG. 8A to FIG. 8D, the shape of the end portion of the dummy optical waveguide 3, which is included in the optoelectronic wiring device 100 according to this embodiment, is described. FIG. 8A to FIG. 8D are top views showing examples of the shape of the end portion (optical terminal end portion) of the dummy optical waveguide 3. In these examples, the light that is incident on the dummy optical input portion is prevented from being reflected and returned from the dummy optical input portion. FIG. 8E shows a C-C cross section of the dummy optical waveguide 3 shown in FIG. 8A to FIG. 8D.

In the example of FIG. 8A, the end portion of the dummy optical waveguide 3 is cut off at 45°, thereby preventing vertical reflection at the end portion. In the example of FIG. 8B, the end portion of the dummy optical waveguide 3 is cut off in a taper shape. Thereby, the amount of light, which is guided, is gradually reduced at the tapered end portion, and thus the light is scattered. In the example of FIG. 8C, the end portion of the dummy optical waveguide 3 is cut in a taper shape. Thereby, the optical waveguide mode is gradually increased at the end portion, and thus the light is scattered. In the example of FIG. 8D, the end portion of the dummy optical waveguide 3 is bent, and the direction of light emission is deflected from the direction of optical waveguide. These examples are workable in combination, and may be implemented in combination.

### MODIFICATIONS

The present invention is not limited to the above-described first to third embodiments. Although the above-described embodiments show some concrete examples, these are merely structural examples, and other means (materials, dimensions) may be applied to the respective elements according to the spirit of the invention. The materials, shapes and dispositions, shown in the embodiments, are merely examples, and the embodiments are workable in combination. For example, although the optical waveguide is formed on the side opposite to the substrate film, the electric wiring may be formed on the optical waveguide, and the optical element may be disposed immediately near the optical input/output portion. Although one light emission part and one light detection part are connected in one-to-one correspondence, it is possible to connect light emission parts and light detection parts in one-to-plurality correspondence (plurality-to-one correspondence) or in plurality-to-plurality correspondence. Other modifications may be made without departing from the spirit of the present invention.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. An optoelectronic wiring board comprising:
an optical wiring including an optical waveguide;
an electrical wiring including an electrically conductive material;
an optical input/output portion which transmits and detects optical signal with and from the optical waveguide;
a dummy optical input portion provided adjacent to the optical input/output portion; and
a dummy optical waveguide which is connected to the dummy optical input portion and has an optical end portion which is provided at an end opposite to the dummy optical input portion and absorbs or scatters light which is incident on the dummy optical input portion.

2. The board according to claim 1,
wherein the dummy optical input portion is disposed on the same line as the optical input/output portion.

3. The board according to claim 1,
wherein the dummy optical input portion and another dummy optical input portion are provided on at least two locations in association for each optical input/output portion.

4. The board according to claim 2,
wherein the dummy optical input portion and another dummy optical input portion are provided on at least two locations in association for each optical input/output portion.

5. The board according to claim 1,
wherein the optical semiconductor device and another optical semiconductor device are formed on the optoelectronic wiring board,
the optical semiconductor device and said another optical semiconductor device are disposed in an array, and
the optical semiconductor device and said another optical semiconductor device optically couple to a optical wirings.

6. The board according to claim 1,
wherein the optical input/output portion is disposed on an intersection of a straight line which connects dummy optical input portions provided at least two locations and extension of the optical wiring.

7. The board according to claim 3,
wherein the dummy optical input portion and another dummy optical input portion which are provided on at least two locations, and the optical input/output portion are disposed on the same line.

8. An optoelectronic wiring board comprising:
a plurality of optical wirings formed in the same direction;
a first dummy optical waveguide which is formed in the same direction as the optical wirings, and includes two optical waveguides which are separated from each other, the two optical waveguides facing each other at one end portion thereof, the first dummy optical waveguide radiating or scattering light, which is incident on the other end portion thereof, at the one end portion;
optical input/output portions which are formed at each of both end portions of the optical wirings, and which input/output an optical signal to/from the optical wirings;
an optical semiconductor device or an external light guide optically coupled to the optical input/output portions; and
first dummy optical input portions which are formed at the other end portion of each of the two optical waveguides included in the first dummy optical waveguide.

9. The board according to claim 8,
wherein one of the optical input/output portions and one of the first dummy optical input portions which is closest to said one of the optical input/output portions are disposed on the same line.

10. The board according to claim 8, further comprising:
a second dummy optical waveguide which is formed in the same direction as the optical wirings, and includes two optical waveguides which are separated from each other, the two optical waveguides facing each other at one end portion thereof, the second dummy optical waveguide radiating or scattering light, which is incident on the other end portion thereof, at the one end portion; and
second dummy optical input portions which are formed at the other end portion of each of the two optical waveguides included in the second dummy optical waveguide,
wherein the second dummy optical waveguide is disposed in parallel to the first dummy optical waveguide, with the optical wirings being interposed between the second dummy optical waveguide and the first dummy optical waveguide.

11. The board according to claim 8, further comprising electrical wiring which is disposed on a peripheral region of the optical input/output portions,
wherein the electrical wiring is disposed at a position which does not contribute to generation of an image.

12. The board according to claim 8,
wherein the optical semiconductor device and another optical semiconductor device are formed on the optoelectronic wiring board,
the optical semiconductor device and said another optical semiconductor device are disposed in an array, and
the optical semiconductor device and said another optical semiconductor device are disposed in accordance with a position where the optical wirings are formed.

13. The board according to claim 10,
wherein one of the optical input/output portions, and one of the first dummy optical input portions and one of the second dummy optical input portions which are closest to said one of the optical input/output portions are disposed on the same line.

14. The board according to claim 10,
wherein a wavelength of the light, which is incident on the first dummy optical input portions and the second dummy optical input portions, is 400 nm to 450 nm.

15. A method of manufacturing a optoelectronic wiring device, comprising:
making light incident on a first dummy optical waveguide through first dummy optical input portions;
subjecting an image, which is acquired from the first dummy optical input portions and a vicinity thereof, to a binarizing process;
recognizing a black part of the image, thereby detecting a position of the first dummy optical input portions; and
disposing an optical semiconductor device or an external light guide on optical input/output portions of an optoelectronic wiring board, by using a result of the detection as an index.

16. The method according to claim 15,
wherein the first dummy optical waveguide is formed in an optoelectronic wiring board, and the first dummy optical input portions include a recess portion which reaches from a surface of the optoelectronic wiring board to the first dummy optical waveguide,
the first dummy optical waveguide includes a mirror in the recess portion, and the mirror reflects the light which is incident in the recess portion to the first dummy optical waveguide, and
a optoelectronic wiring, which is capable of transmitting an electric signal which is obtained by converting an optical signal which is received by the optical semiconductor device or the external light guide, and is disposed on the optoelectronic wiring board at a position excluding the first dummy optical input portions.

17. The method according to claim 15, further comprising forming an optical wiring which is capable of transmitting an optical signal, and a first dummy optical waveguide which is formed in the same direction as the optical wiring and includes two optical waveguides which are separated from each other, the two optical waveguides facing each other at one end portion thereof,
wherein the optical input/output portions are formed at each of both end portions of the optical wiring,
the first dummy optical input portions are formed at the other end portion of each of the two optical waveguides included in the first dummy optical waveguide, and
the optical input/output portions and the first dummy optical input portions are formed in the same process.

18. The method according to claim 17, further comprising forming a second dummy optical waveguide which is formed in the same direction as the optical wiring and includes two optical waveguides which are separated from each other, the two optical waveguides facing each other at one end portion thereof,
wherein second dummy optical input portions are formed at the other end portion of each of the two optical waveguides included in the second dummy optical waveguide,
the second dummy optical input portions are formed in the same process as the optical input/output portions and the first dummy optical input portions, and
one of the optical input/output portions, and one of the first dummy optical input portions and one of the second dummy optical input portions which are closest to one of the optical input/output portions, are disposed on the same line.

19. The method according to claim 18,
wherein the image is formed by making light with a wavelength of 400-450 nm incident on the first dummy optical input portions.

20. The method according to claim 19,
wherein the other end portions of the optical waveguides included in the first and second dummy optical input portions are formed in a manner to cause the light, which is incident on the first dummy optical input portions, and the light, which is incident on the second dummy optical input portion, to be absorbed or scattered within the optoelectronic wiring board.
